(19) United States
(12) Patent Application Publication
(10) Pub. No.: US 2023/0069568 A1
(43) Pub. Date: Mar. 2, 2023

(54) MANUFACTURING METHOD OF SEMICONDUCTOR DEVICE

(71) Applicant: FUJI ELECTRIC CO., LTD., Kanagawa (JP)

(72) Inventor: Tsutomu KATO, Matsumoto-city (JP)

(21) Appl. No.: 17/844,733

(22) Filed: Jun. 21, 2022

(30) Foreign Application Priority Data
Aug. 31, 2021 (JP) 2021-140625

(51) Int. Cl. H01L 21/463; H01L 21/47

(52) U.S. Cl. CPC H01L 21/463; H01L 21/47

(57) ABSTRACT

Provided is a manufacturing method of a semiconductor device including a semiconductor substrate having an upper surface. The manufacturing method includes forming a trench on the upper surface of the semiconductor substrate, arranging a material by arranging a surface-treatment material on the upper surface of the semiconductor substrate and the surface of the trench, applying a resist to an interior of the trench, and patterning the resist by exposing the resist using a mask to leave the resist in the interior of the trench predetermined. Surface free energy of solids of the surface-treatment material is less than surface free energy of liquids of the resist.

The contents of the following Japanese patent application are incorporated herein by reference:

NO. 2021-140625 filed in JP on Aug. 31, 2021.

### BACKGROUND

### 1. Technical Field

The present invention relates to a manufacturing method of a semiconductor device.

### 2. Related Art

Conventionally in manufacturing methods of semiconductor devices, technologies relating to methods of embedding trench grooves having a high aspect ratio, including formation of trench isolation regions in a semiconductor substrate, are known. (See Patent Document 1, for example).

Patent Document 1: Japanese Patent Application Publication No. 2004-363615

### BRIEF DESCRIPTION OF DRAWINGS

FIG. 1 is a diagram illustrating a comparative example of a flow chart of a manufacturing method of a semiconductor device 100.

FIG. 2 is a diagram illustrating a comparative example of the manufacturing method of the semiconductor device 100.

FIG. 3 is a diagram illustrating a comparative example of the manufacturing method of the semiconductor device 100.

FIG. 4 is a diagram illustrating an example embodiment of a flow chart of the manufacturing method of the semiconductor device 100.

FIG. 5 is a diagram illustrating an example embodiment of the manufacturing method of the semiconductor device 100.

FIG. 6 is a diagram illustrating an example embodiment of the manufacturing method of the semiconductor device 100.

FIG. 7 is a diagram illustrating surface free energy of solids of a surface-treatment material 80 and surface free energy of liquids of a resist 130.

FIG. 8 is a diagram for illustrating another example of the manufacturing method of the semiconductor device 100.

FIG. 9 shows one example of an arrangement of a trench 45.

FIG. 10 shows a cross section taken along a-a in FIG. 9.

FIG. 11 shows a cross section taken along b-b in FIG. 9.

FIG. 12 shows another example of the arrangement of the trench 45.

FIG. 13 shows a cross section taken along c-c in FIG. 12.

FIG. 14 shows a cross section taken along d-d in FIG. 12.

FIG. 15 is a diagram for illustrating the trench 45 and a dummy trench 35.

### DESCRIPTION OF EXEMPLARY EMBODIMENTS

Hereinafter, the invention will be described through embodiments of the invention, but the following embodiments do not limit the invention according to claims. In addition, not all combinations of features described in the embodiments are essential to the solution of the invention. In the present specification and the drawings, a repeated description for an element having substantially the same function and configuration is omitted by providing the same reference numeral, and illustration of an element which is not directly associated with the present invention is omitted. Also, regarding elements in one drawing having the same function and configuration, only one of the elements may have a reference numeral, reference numerals for other elements being omitted.

In the present specification, one side in a direction parallel to a depth direction of a semiconductor substrate is referred to as “upper” and the other side is referred to as “lower”. One surface of two principal surfaces of a substrate, a layer or other member is referred to as an upper surface, and the other surface is referred to as a lower surface. An “upper” and “lower” direction is not limited to a direction of gravity, or a direction at the time in which the semiconductor module is implemented.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. A +Z axis direction and a -Z axis direction are directions opposite to each other. When the Z axis direction is described without describing the signs, it means that the direction is parallel to the +Z axis and the -Z axis. In the present specification, orthogonal axes parallel to the upper surface and the lower surface of the semiconductor substrate are referred to as an X axis and a Y axis. Also, an axis perpendicular to the upper surface and the lower surface of the semiconductor substrate is referred to as a Z axis. In the present specification, the direction of the Z axis may be referred to as a depth direction. Also, in the present specification, a direction parallel to the upper surface and the lower surface of the semiconductor substrate may be referred to as a horizontal direction, including an X axis direction and a Y axis direction.

In the present specification, a case where a term such as “same” or “equal” is mentioned may include a case where an error due to a variation in manufacturing or the like is included. The error is, for example, within 10%.

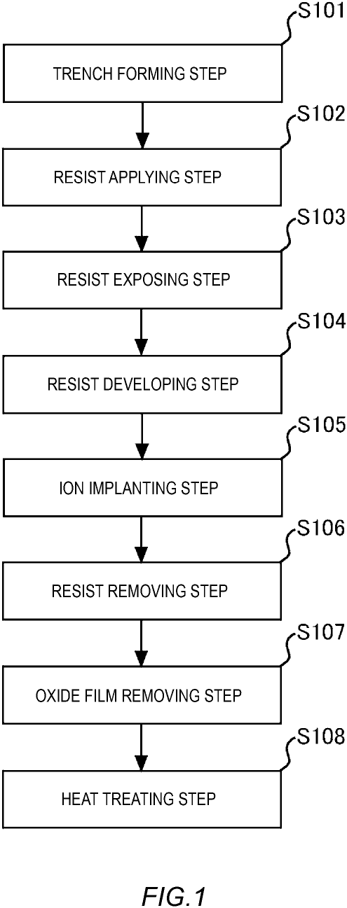

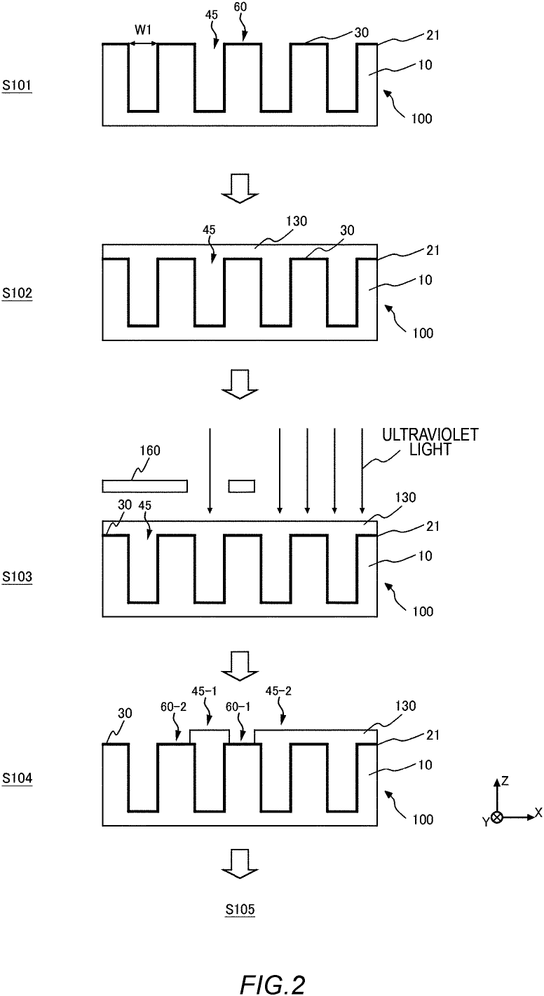

FIG. 1 is a diagram illustrating a comparative example of a flow chart of a manufacturing method of a semiconductor device 100 (See FIG. 2). The manufacturing method of the semiconductor device 100 includes trench forming step S101, resist applying step S102, resist exposing step S103, resist developing step S104, ion implanting step S105, resist removing step S106, oxide film removing step S107 and heat treating step S108.

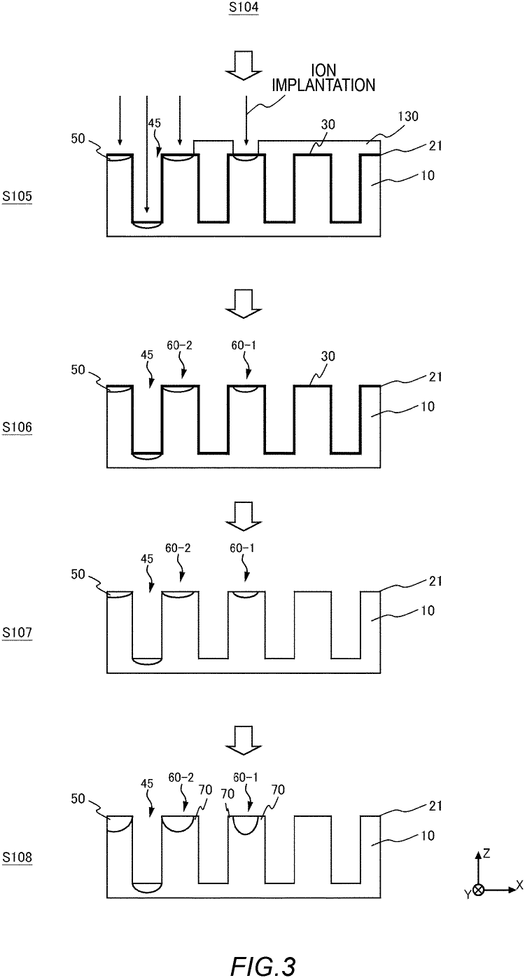

FIGS. 2 and 3 are diagrams illustrating a comparative example of the manufacturing method of the semiconductor device 100. In FIG. 2, the trench forming step S101, the resist applying step S102, the resist exposing step S103 and the resist developing step S104 are illustrated. In FIG. 3, the ion implanting step S105, the resist removing step S106, the oxide film removing step S107, and the heat treating step S108 are illustrated.

The semiconductor device 100, as one example, functions as a power conversion apparatus such as an inverter. The semiconductor device 100 may include an insulated gate bipolar transistor (IGBT); a diode such as an FWD (Free Wheel Diode); an RC (Reverse Conducting)-IGBT provided by combining the IGBT and the FWD; and a MOS transistor, or the like. The semiconductor device 100 may not be limited to these examples.

The semiconductor device 100 is provided on a semiconductor substrate 10. Accordingly, the semiconductor device 100 includes the semiconductor substrate 10. The semiconductor substrate 10 in the present example is a wafer whose shape seen from the top is almost circular. The semiconductor substrate 10 is formed of a semiconductor material. The semiconductor substrate 10 is a silicon substrate as one example, but a material of the semiconductor substrate 10 is not limited to silicon. Also, the semiconductor substrate 10 has an upper surface 21 and a lower surface (not shown). In FIG. 2, a part of the upper surface 21 of the semiconductor substrate 10 is shown.

The upper surface 21 of the semiconductor substrate 10 may be a surface on which a gate structure such as an IGBT or a MOS transistor is formed. The gate structure includes at least one of a gate electrode, a gate insulating film, a source region, an emitter region and a channel region, for example. The upper surface 21 of the semiconductor substrate 10 may be a so-called device surface.

In the trench forming step S101, a trench 45 is formed in the upper surface 21 of the semiconductor substrate 10. The trench 45 is, as one example, a groove in which the gate electrode of the gate structure is formed. The trench 45 may be formed by etching. The trench 45 may be etched by known methods. The trench 45, as one example, is formed by dry etching. A mesa portion 60 is provided between the trenches 45 adjacent to each other. The width W1 of the trench 45 is, as one example, 1 µm or less.

In the trench forming step S101, an oxide film 30 is also formed. In the present example, the oxide film 30 is formed on the upper surface 21 of the semiconductor substrate 10 and a surface of the trench 45. In the present specification, the surface of the trench 45 includes a side wall and a bottom portion of the trench 45. The oxide film 30 may be a thermally oxidized film. The oxide film 30 may be formed by known methods. The formation of the oxide film 30 on the upper surface 21 of the semiconductor substrate 10 and the surface of the trench 45 allows preventing metal contamination, and channeling due to ion implantation.

In the resist applying step S102, a resist 130 is applied to the upper surface 21 of the semiconductor substrate 10 and an interior of the trench 45. In the present example, the resist 130 is a negative resist. The resist 130 may include a photosensitive material.

In the resist exposing step S103, the resist 130 is exposed. In the present example, the resist 130 is exposed with an ultraviolet light. Also, in the resist exposing step S103, the resist 130 is exposed using a mask 160. Since the resist 130 is a negative resist, solubility of the exposed area to a developer solution can be reduced.

In the resist developing step S104, the resist 130 is developed. For example, the resist 130 is developed using the developer solution. The developer solution, as one example, is an alkaline chemical. The developer solution may be an organic solvent. Since the solubility of the exposed area is reduced, the resist 130 can be patterned. In the resist developing step S104, the resist is left in the interior of the trench 45 predetermined. The resist exposing step S103 and the resist developing step S104 are examples of a resist patterning step.

A thickness of the resist 130 provided on the mesa portion 60 is about 1 µm, whereas a thickness of the resist 130 provided on the trench 45 is about 5 µm or greater. Consequently, a difference between the thicknesses of the resists provided may cause resist cracking. In the present example, in order to prevent the cracking of the resist 130, it is preferred that the resist 130 be not provided on the mesa portion 60-1 and the mesa portion 60-2.

In the present example, the resist 130 is patterned in such a way that the resist 130 is provided on the trench 45-1 and the trench 45-2. The resist 130 has positional displacement errors of from 0.1 µm to 0.3 µm, therefore a variation must be secured. In the present example, in order to secure the variation, the resist 130 is provided on the mesa portion 60-1 in a proximity to the trench 45-1 and the mesa portion 60-1 in a proximity to the trench 45-2. Also, the resist 130 is provided on the mesa portion 60-2 in the proximity to the trench 45-1.

In the ion implanting step S105, ions are implanted into the upper surface 21 of the semiconductor substrate 10. In the present example, p-type dopants such as boron are implanted into the upper surface 21 of the semiconductor substrate 10 An acceleration energy of the ion implantation is, as one example, about 150 keV. A dose amount of the ion implantation is, as one example, about 3 × 10⁻¹³ atoms/cm². By implanting the p-type dopants, a p-type region 50 can be formed. The ion implantation may be performed by an ion implantation apparatus.

In the resist removing step S106, the resist 130 is removed. The resist 130 may be removed by oxygen plasma. The resist 130 may be removed by a chemical liquid.

In the oxide film removing step S107, the oxide film 30 formed in the trench forming step S101 is removed. The oxide film 30 may be removed by a chemical liquid such as hydrofluoric acid.

In the heat treating step S108, the semiconductor substrate 10 is heat treated. In the present example, the semiconductor substrate 10 is heat treated at 500° C. or greater, for example, 1000° C. Heat treating the semiconductor substrate 10 allows ion species in the p-type region 50 to be diffused. Properties such as turn-on power loss can be improved by providing the p-type region 50 at the bottom portion of the trench 45.

In the present example, a non-diffused region 70 is formed in the mesa portion 60-1 and the mesa portion 60-2. The non-diffused region 70 is a region in which the p-type region 50 is not formed. In the resist patterning step, the resist 130 is provided on a part of the mesa portion 60-1 and a part of the mesa portion 60-2, therefore, the non-diffused region 70 is formed. If the non-diffused region 70 is formed in the upper surface 21 of the semiconductor substrate 10, a characteristic change of the semiconductor device 100 may occur. In order to prevent the characteristic change of the semiconductor device 100, it is preferred that the non-diffused region 70 be not formed in the upper surface 21 of the semiconductor substrate 10.

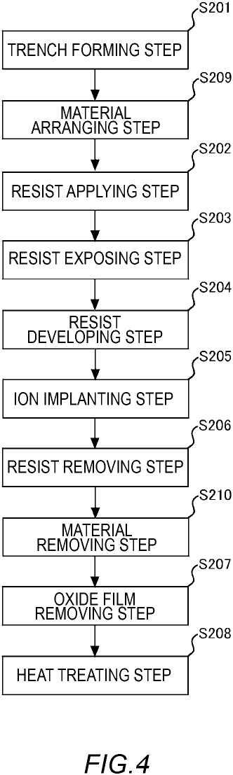

FIG. 4 is a diagram illustrating an example embodiment of a flow chart of the manufacturing method of the semiconductor device 100. The manufacturing method of the semiconductor device 100 includes trench forming step S201, material arranging step S209, resist applying step S202, resist exposing step S203, resist developing step S204, ion implanting step S205, resist removing step S206, material removing step S210, oxide film removing step S207, and heat treating step S208.

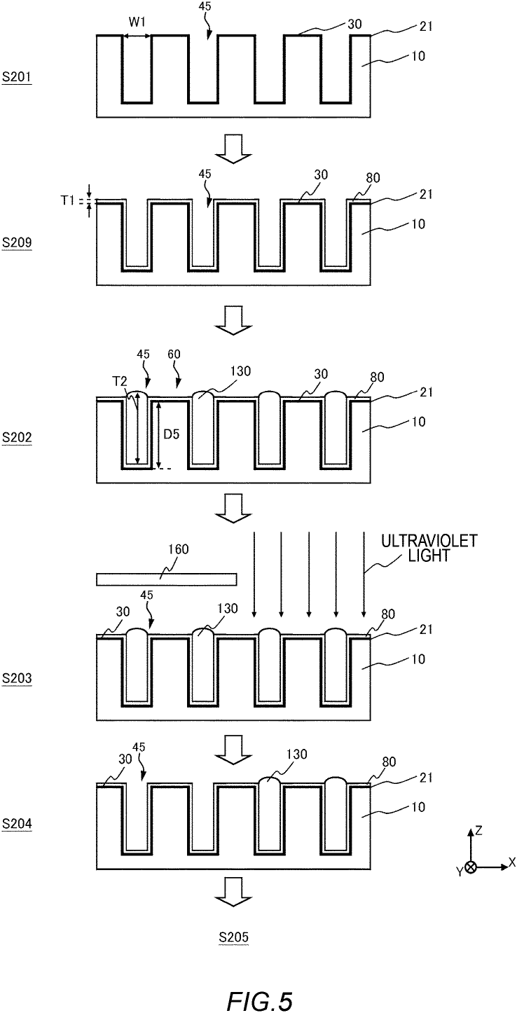

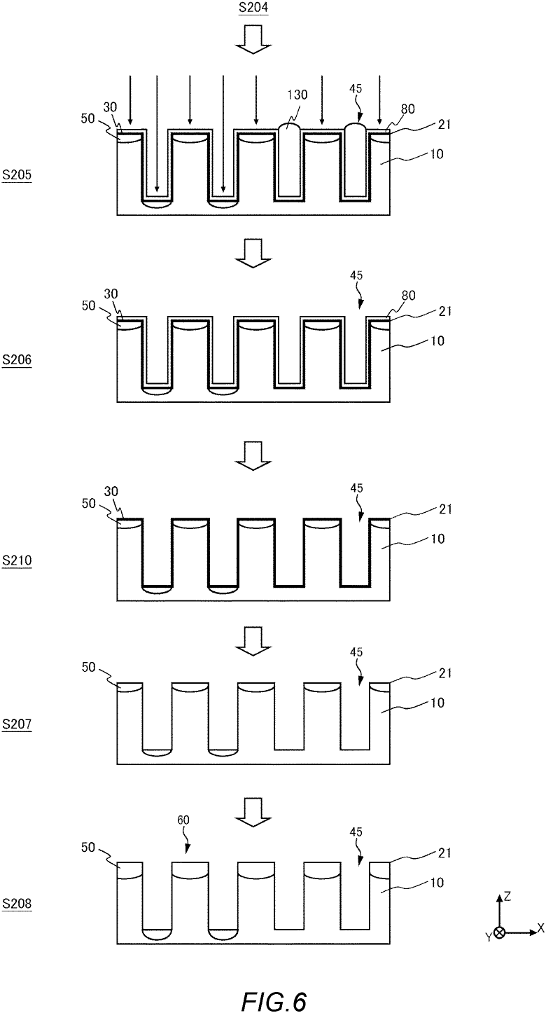

FIGS. 5 and 6 are diagrams illustrating an example embodiment of the manufacturing method of the semiconductor device 100. In FIG. 5, the trench forming step S201, the material arranging step S209, the resist applying step S202, the resist exposing step S203 and the resist developing step S204 are illustrated. In FIG. 6, the ion implanting step S205, the resist removing step S206, the material removing step S210, the oxide film removing step S207 and the heat treating step S208 are illustrated. The trench forming step S201 may be the same as the trench forming step S101 in FIG. 2.

In the material arranging step S209, a surface-treatment material 80 is arranged on the upper surface 21 of the semiconductor substrate 10 and the surface of the trench 45. The surface-treatment material 80 reduces surface free energy of solids of a surface of the semiconductor substrate 10. In the present example, surface free energy of solids of the surface-treatment material 80 is less than surface free energy of liquids of the resist 130. The surface free energy of solids of the surface-treatment material 80 may be less than the surface free energy of solids of the upper surface 21 of the semiconductor substrate 10. The surface free energy of solids of the surface-treatment material 80 may be less than surface free energy of solids of the oxide film 30. In order to reduce the surface free energy of solids of the surface-treatment material 80, it is preferred that the surface-treatment material 80 be a material having a higher content ratio of carbon-fluorine bond.

The surface free energy of solids of the surface-treatment material 80 may be 20 mN/m or less. The surface free energy of solids of the surface-treatment material 80 may be 10 mN/m or less. By controlling the surface free energy of solids of the surface-treatment material 80 to be 20 mN/m or less, the surface free energy of solids of the surface-treatment material 80 can be less than the surface free energy of liquids of the resist 130. The surface free energy of liquids of the resist 130 may be 40 mN/m or less.

A viscosity of the surface-treatment material 80 may be 10 cP or less. The viscosity of the surface-treatment material 80 may be 5 cP or less. By controlling the viscosity of the surface-treatment material 80 to be 10 cP or less, a thickness T1 of the surface-treatment material 80 arranged can be small. By controlling the thickness T1 of the surface-treatment material 80 arranged to be small, the surface-treatment material 80 can be readily removed in the material removing step S210. The viscosity of the surface-treatment material 80 can be adjusted by adding an organic solvent to the surface-treatment material 80.

The thickness T1 of the surface-treatment material 80 arranged may be 0.1 µm or greater and 0.3 µm or less. By controlling the thickness T1 of the surface-treatment material 80 arranged to be 0.1 µm or more and 0.3 µm or less, the characteristic change of the semiconductor device 100 can be suppressed, and the surface-treatment material 80 can be readily removed in the material removing step S210.

The surface-treatment material 80 may be arranged by spin-coating. The surface-treatment material 80 can be arranged by a common coating method, such as bar-coating, slit-coating, dispensing and screen-printing. In the material arranging step S209, the surface-treatment material 80 may be applied to be solidified. In the material arranging step S209, the surface-treatment material 80 may be vapor-deposited. Also, the surface-treatment material 80 may be arranged by vapor phase growth.

In the resist applying step S202, the resist 130 is applied to the interior of the trench 45. In the present example, since the surface-treatment material 80 is arranged on the upper surface 21 of the semiconductor substrate 10 and the surface of the trench 45, the resist 130 at the upper surface 21 of the semiconductor substrate 10 flows. Accordingly, unlike the resist applying step S102 in FIG. 2, the resist 130 is not provided on the mesa portion 60. Also, the resist 130 may be provided in a position higher than that of the upper surface 21 of the semiconductor substrate 10. Since the resist 130 at the upper surface 21 of the semiconductor substrate 10 flows, it is preferred that the semiconductor substrate 10 remain still for 10 minutes or longer.

A thickness T2 of the resist 130 may be greater than or equal to 25% of a depth D5 of the trench 45. The thickness T2 of the resist 130 may be a maximum thickness of the resist 130. The depth D5 of the trench 45 may be a maximum depth of the trench 45. In the present example, the thickness T2 of the resist 130 is greater than or equal to the depth D5 of the trench 45. In other words, at least part of the resist 130 may be provided in the position higher than that of the upper surface 21 of the semiconductor substrate 10 in a height direction.

In the resist exposing step S203, the resist 130 is exposed. In the present example, the resist 130 is exposed with an ultraviolet light. Also, in the resist exposing step S203, the resist 130 is exposed using the mask 160. Since the resist 130 is a negative resist, solubility of the exposed area to a developer solution can be reduced.

In the resist developing step S204, the resist 130 is developed. For example, the resist 130 is developed using the developer solution. The developer solution, as one example, is an alkaline chemical. The developer solution may be an organic solvent. Since the solubility of the exposed area is reduced, the resist 130 can be patterned. In the resist developing step S204, the resist is left in the interior of the trench 45 predetermined. The resist exposing step S203 and the resist developing step S204 are examples of a resist patterning step.

In the ion implanting step S205, ions are implanted into the upper surface 21 of the semiconductor substrate 10. In the present example, p-type dopants such as boron are implanted into the upper surface 21 of the semiconductor substrate 10 An acceleration energy of the ion implantation is, as one example, about 150 keV. A dose amount of the ion implantation is, as one example, about 3×10⁻¹³ atoms/cm². Implanting the p-type dopants allows a p-type region 50 to be formed. The ion implantation may be performed by an ion implantation apparatus.

In the resist removing step S206, the resist 130 is removed. The resist 130 may be removed by oxygen plasma. The resist 130 may be removed by a chemical liquid.

In the material removing step S210, the surface-treatment material 80 is removed. The surface-treatment material 80 is removed by plasma containing, for example, about 10% CF₄ and nitrogen. The surface-treatment material 80 may be removed by the chemical liquid.

In a state in which the surface-treatment material 80 is arranged, heat treating at a temperature greater than 200° C. may cause alteration or deformation of the surface-treatment material 80. Accordingly, it is preferred that each of from the material arranging step S209 to the material removing step S210 be performed at a temperature of 200° C. or less.

In the oxide film removing step S207, the oxide film 30 formed in the trench forming step S201 is removed. The oxide film 30 may be removed by a chemical liquid such as hydrofluoric acid.

In the heat treating step S208, the semiconductor substrate 10 is heat treated. In the present example, the semiconductor substrate 10 is heat treated at 500° C. or greater, for example, 1000° C. Heat treating the semiconductor substrate 10 allows ion species in the p-type region 50 to be diffused. Also, performing the heat treating step S208 after the resist removing step S206 and the material removing step S210 can prevent the deformation of the resist 130 and the surface-treatment material 80 and the like.

In the present example, unlike FIG. 3, the non-diffused region is not formed in the mesa portion 60. Accordingly, by providing the surface-treatment material 80, the characteristic change of the semiconductor device 100 can be prevented from occurring.

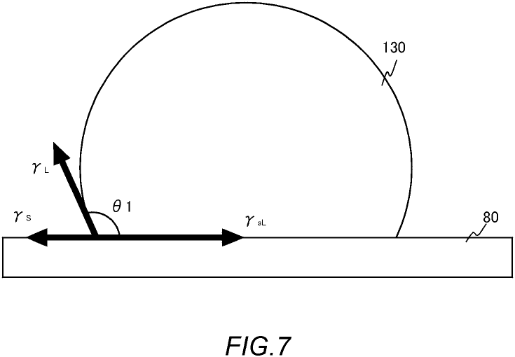

FIG. 7 is a diagram illustrating surface free energy of solids of the surface-treatment material 80 and surface free energy of liquids of the resist 130. In FIG. 7, the surface free energy of solids of the surface-treatment material 80 is denoted as γₛ. The surface free energy of solids may be surface tension of solids. The surface free energy of liquids of the resist 130 is denoted as γ_{L}. The surface free energy of liquids of the resist 130 may be the surface free energy of liquids of the resist 130 when applied. The surface free energy of liquids may be surface tension of liquids. Also, interfacial tension of the surface-treatment material 80 and the resist 130 is denoted as γ_{sL.} A contact angle between the resist 130 and the surface-treatment material 80 is denoted as θ1. A relationship between the surface free energy of solids of the surface-treatment material 80 and the surface free energy of liquids of the resist 130 is represented as Formula 1 below.

$${γ}_{\text{s}} = {γ}_{\text{L}} ⋅ \text{cos} θ \text{1} \text{+} {γ}_{\text{sL}}$$

The surface free energy of solids γₛ of the surface-treatment material 80 is less than the surface free energy of liquids γ_{L} of the resist 130. Accordingly, the contact angle θ1 tends to be greater compared to when the surface free energy of solids γₛ of the surface-treatment material 80 is greater than the surface free energy of liquids γ_{L} of the resist 130, according to Formula 1. In FIG. 7, the contact angle θ1 is 90° or greater. Accordingly, a surface of the semiconductor substrate 10 provided with the surface-treatment material 80 has lower wettability to allow the resist 130 to easily flow.

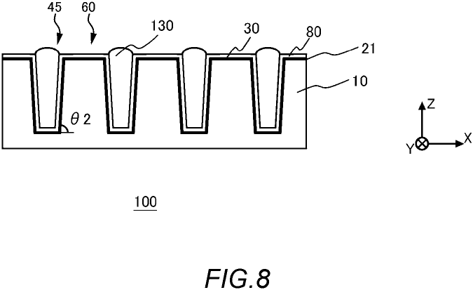

FIG. 8 is a diagram for illustrating another example of the manufacturing method of the semiconductor device 100. FIG. 8 shows another example of the resist applying step S202. The resist applying step S202 in the present example is different from the resist applying step S202 in FIG. 5 in that the trench 45 has a tapered shape. Configurations other than that in FIG. 8 may be the same as the resist applying step S202 in FIG. 5.

The tapered shape may be a design in which an opening of the trench 45 is larger than the bottom portion of the trench 45. Since the trench 45 has the tapered shape, the resist 130 easily flows into the interior of the trench 45. An angle θ2 between the side wall of the trench 45 and the bottom portion of the trench 45 may be 70° or greater. The angle θ2 between the side wall of the trench 45 and the bottom portion of the trench 45 may be 80° or greater. The trench 45 may have a predetermined shoulder portion.

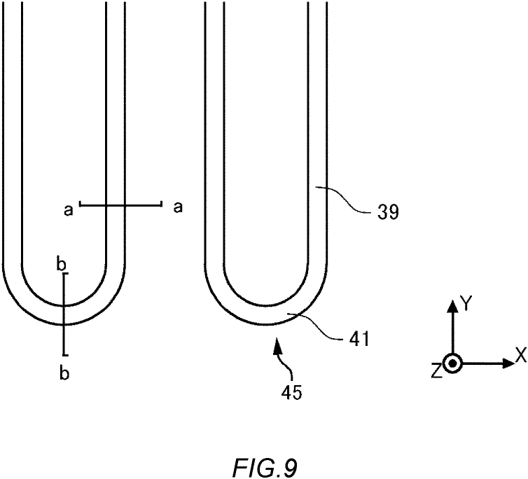

FIG. 9 shows one example of an arrangement of the trench 45. FIG. 9 shows the trench 45 in a top view.

In the present example, the trench 45 has an extending portion 39 and a connecting portion 41. The extending portion 39 extends in a predetermined direction. In FIG. 9, the extending portion 39 extends in a Y axis direction. The connecting portion 41 connects the extending portion 39. In FIG. 9, the connecting portion 41 connects the extending portion 39 in an X axis direction.

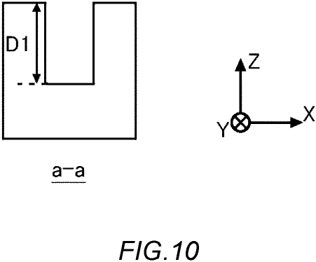

FIG. 10 shows a cross section taken along a-a in FIG. 9. FIG. 10 shows an X-Z cross section passing through the extending portion 39 of the trench 45. In FIG. 10, only a proximity of the upper surface 21 of the semiconductor substrate 10 is shown, and a proximity of the lower surface of the semiconductor substrate 10 is omitted.

In the present example, the extending portion 39 of the trench 45 has a depth D1. The depth D1 of the extending portion 39 of the trench 45 may be a maximum depth of the extending portion 39 of the trench 45.

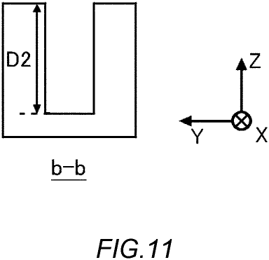

FIG. 11 shows a cross section taken along b-b in FIG. 9. FIG. 11 shows a Y-Z cross section passing through the connecting portion 41 of the trench 45. In FIG. 11, only the proximity of the upper surface 21 of the semiconductor substrate 10 is shown, and the proximity of the lower surface of the semiconductor substrate 10 is omitted.

In the present example, the connecting portion 41 of the trench 45 has a depth D2. The depth D2 of the connecting portion 41 of the trench 45 may be a maximum depth of the connecting portion 41 of the trench 45.

The depth D2 of the connecting portion 41 of the trench 45 may be greater than the depth D1 of the extending portion 39 of the trench 45. In other words, the connecting portion 41 of the trench 45 is formed deeper than the extending portion 39 of the trench 45. The connecting portion 41 of the trench 45 deeper than the extending portion 39 of the trench 45 allows the resist 130 to easily flow to the connecting portion 41 of the trench 45 in the resist applying step S202. Also, the characteristic change of the semiconductor device 100 is not likely to occur even if a shape of the connecting portion 41 of the trench 45 is modified.

In the trench forming step S201, the connecting portion 41 of the trench 45 is formed deeper than the extending portion 39 of the trench 45. The connecting portion 41 of the trench 45 may be formed more shallowly as approaching the extending portion 39 of the trench 45. The depth D2 of the connecting portion 41 of the trench 45 may continuously vary.

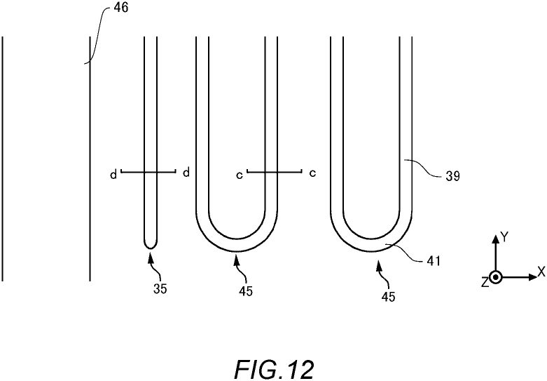

FIG. 12 shows another example of the arrangement of the trench 45. FIG. 12 shows the trench 45 in a top view. Also in the present example, the trench 45 has the extending portion 39 and the connecting portion 41. Also in the present example, arrangements of a dummy trench 35 and a gate wiring 46 are shown.

The gate wiring 46 connects with the gate electrode. Also, the gate wiring 46 may connect with a gate pad. The gate wiring 46 outputs a gate potential applied to the gate pad to the gate electrode. In FIG. 12, the gate wiring 46 extends in a Y axis direction. The gate wiring 46 may enclose an active section of the semiconductor device 100 in a top view. The gate wiring 46 may be a metal wiring including aluminum and the like.

The dummy trench 35 is a trench in which the gate electrode is not formed. An insulating film may be provided in an interior of the dummy trench 35. The dummy trench 35 extends in a predetermined direction. In FIG. 12, the dummy trench 35 extends in the Y axis direction.

In the present example, the dummy trench 35 is provided closer to an outer side of the semiconductor substrate 10 than the trench 45 is. The outer side of the semiconductor substrate 10 is a gate wiring 46 side. In other words, the dummy trench 35 is provided closer to the gate wiring 46 than the trench 45 is. Also, the outer side of the semiconductor substrate 10 may be an opposite side of the active section of the semiconductor device 100. In the trench forming step S201, the dummy trench 35 is formed closer to the outer side of the semiconductor substrate 10 than the trench 45 is.

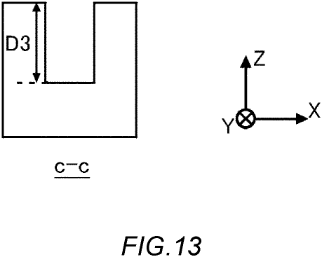

FIG. 13 shows a cross section taken along c-c in FIG. 12. FIG. 13 shows an X-Z cross section passing through the extending portion 39 of the trench 45. In FIG. 13, only the proximity of the upper surface 21 of the semiconductor substrate 10 is shown, and the proximity of the lower surface of the semiconductor substrate 10 is omitted.

In the present example, the extending portion 39 of the trench 45 has a depth D3. The depth D3 of the extending portion 39 of the trench 45 may be a maximum depth of the extending portion 39 of the trench 45.

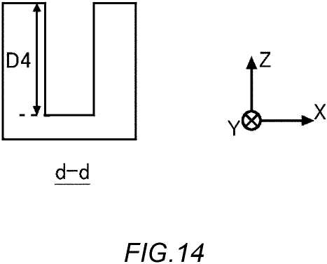

FIG. 14 shows a cross section taken along d-d in FIG. 12. FIG. 14 shows an X-Z cross section passing through the dummy trench 35. In FIG. 14, only the proximity of the upper surface 21 of the semiconductor substrate 10 is shown, and the proximity of the lower surface of the semiconductor substrate 10 is omitted.

In the present example, the dummy trench 35 has a depth D4. The depth D4 of the dummy trench 35 may be a maximum depth of the dummy trench 35.

The depth D4 of the dummy trench 35 is greater than the depth D3 of the extending portion 39 of the trench 45. In other words, the dummy trench 35 is formed deeper than the extending portion 39 of the trench 45. Also, the dummy trench 35 may be formed deeper than the connecting portion 41 of the trench 45. The dummy trench 35 deeper than the trench 45 allows the resist 130 to easily flow to the dummy trench 35 in the resist applying step S202. Also, since the dummy trench 35 is a trench in which the gate electrode is not formed, the characteristic change of the semiconductor device 100 is not likely to occur even if the depth D4 of the dummy trench 35 is greater. The depth D4 of the dummy trench 35 may be almost the same as the depth D3 of the extending portion 39 of the trench 45.

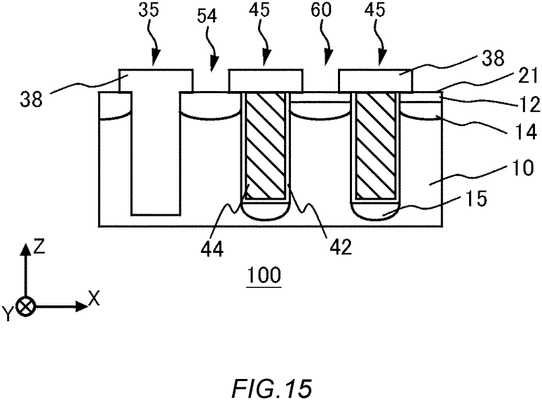

FIG. 15 is a diagram for illustrating the trench 45 and the dummy trench 35. This cross section is an X-Z plane passing through an emitter region 12. In the cross section, the semiconductor device 100 of the present example has the semiconductor substrate 10 and an interlayer dielectric film 38. In FIG. 15, only the proximity of the upper surface 21 of the semiconductor substrate 10 is shown, and the proximity of the lower surface of the semiconductor substrate 10 is omitted.

The interlayer dielectric film 38 includes at least one layer of an insulating film such as silicate glass added with impurities such as boron or phosphorus, thermally oxidized film and other insulating films. The interlayer dielectric film 38 is provided with a contact hole 54.

In each mesa portion 60, a base region 14 is provided. The mesa portion 60 has the emitter region 12 exposing on the upper surface 21 of the semiconductor substrate 10. The emitter region 12 is provided in contact with the trench 45. Also, the mesa portion 60 in contact with the trench 45 may have a contact region exposing on the upper surface 21 of the semiconductor substrate 10.

A bottom region 15 is provided at the bottom portion of the trench 45. The bottom region 15 may not be provided at a bottom portion of the dummy trench 35. The base region 14 and the bottom region 15 are examples of the p-type region described above.

The trench 45 has a gate insulating film 42 and a gate electrode 44 provided in its interior. The gate insulating film 42 is provided to cover an inner wall of the trench 45. The gate insulating film 42 may be formed by oxidizing or nitriding the semiconductor material of the inner wall of the trench 45. The gate electrode 44 is provided inside the gate insulating film 42 in the interior of the trench 45. In other words, the gate insulating film 42 insulates the gate electrode 44 from the semiconductor substrate 10. The gate electrode 44 is formed of a conductive material such as polysilicon.

The gate electrode 44 may be longer than the base region 14 in a depth direction. In the cross section, the trench 45 is covered with the interlayer dielectric film 38 at the upper surface 21 of the semiconductor substrate 10. The gate electrode 44 is electrically connected by a gate runner or the like. The gate electrode 44 may be connected with a gate pad. When a predetermined voltage is applied to the gate electrode 44, a channel is formed by an electron inversion layer in an interfacing surface layer of the base region 14 in contact with the trench 45.

The interlayer dielectric film 38 may be provided in the interior of the dummy trench 35. Also, the interlayer dielectric film 38 may be provided above the dummy trench 35. Since the interlayer dielectric film 38 is provided in the interior of the dummy trench 35, a channel is not formed in the interfacing surface layer of the base region 14 in contact with the dummy trench 35.

While the embodiments of the invention have been described, the technical scope of the invention is not limited to the above described embodiments. It is apparent to persons skilled in the art that various modifications or improvements can be added to the above described embodiments. It is also apparent from the scope of the claims that the embodiments added with such modifications or improvements can be included in the technical scope of the present invention.

What is claimed is:

1. A manufacturing method of a semiconductor device comprising a semiconductor substrate having an upper surface, the manufacturing method comprising:
forming a trench on the upper surface of the semiconductor substrate;
arranging a material by arranging a surface-treatment material on the upper surface of the semiconductor substrate and a surface of the trench;
applying a resist to an interior of the trench; and
patterning the resist by exposing the resist using a mask to leave the resist in the interior of the trench predetermined,
wherein surface free energy of solids of the surface-treatment material is less than surface free energy of liquids of the resist.

2. The manufacturing method of a semiconductor device according to claim 1, wherein
the surface free energy of solids of the surface-treatment material is 20 mN/m or less.

3. The manufacturing method of a semiconductor device according to claim 1, wherein
a viscosity of the surface-treatment material is 10 cP or less.

4. The manufacturing method of a semiconductor device according to claim 1, wherein
a thickness of the surface-treatment material arranged is 0.1 µm or greater and 0.3 µm or less.

5. The manufacturing method of a semiconductor device according to claim 1, wherein
a thickness of the resist is greater than or equal to 25% of a depth of the trench.

6. The manufacturing method of a semiconductor device according to claim 1, wherein
in the arranging the material, the surface-treatment material is applied to be solidified.

7. The manufacturing method of a semiconductor device according to claim 1, wherein
in the arranging the material, the surface-treatment material is vapor-deposited.

8. The manufacturing method of a semiconductor device according to claim 1, further comprising:
implanting ions into the upper surface of the semiconductor substrate;
removing the resist; and
removing the material by removing the surface-treatment material, wherein
each of from the arranging the material to the removing the material is performed at a temperature of 200° C. or less.

9. The manufacturing method of a semiconductor device according to claim 8, further comprising:
heat treating by heat treating the semiconductor substrate at 500° C. or greater after the removing the resist and the removing the material.

10. The manufacturing method of a semiconductor device according to claim 1, wherein
the resist is a negative resist.

11. The manufacturing method of a semiconductor device according to claim 1, wherein
the trench has a tapered shape.

12. The manufacturing method of a semiconductor device according to claim 1, wherein
the trench has an extending portion extending in a predetermined direction, and a connecting portion connecting the extending portion, and
in the forming the trench, the connecting portion is formed deeper than the extending portion.

13. The manufacturing method of a semiconductor device according to claim 1, wherein
in the forming the trench, a dummy trench is formed closer to an outer side of the semiconductor substrate than the trench is.

14. The manufacturing method of a semiconductor device according to claim 2, wherein
a thickness of the resist is greater than or equal to 25% of a depth of the trench.

15. The manufacturing method of a semiconductor device according to claim 3, wherein
a thickness of the resist is greater than or equal to 25% of a depth of the trench.

16. The manufacturing method of a semiconductor device according to claim 4, wherein
a thickness of the resist is greater than or equal to 25% of a depth of the trench.

17. The manufacturing method of a semiconductor device according to claim 2, wherein
in the arranging the material, the surface-treatment material is applied to be solidified.

18. The manufacturing method of a semiconductor device according to claim 3, wherein
in the arranging the material, the surface-treatment material is applied to be solidified.

19. The manufacturing method of a semiconductor device according to claim 4, wherein
in the arranging the material, the surface-treatment material is applied to be solidified.

20. The manufacturing method of a semiconductor device according to claim 5, wherein
in the arranging the material, the surface-treatment material is applied to be solidified.
